(19) United States
(12) Patent Application Publication
(10) Pub. No.: US 2012/0181075 A1
(43) Pub. Date: Jul. 19, 2012

(54) FLEXIBLE FLAT CABLE ASSEMBLY AND METHOD OF MANUFACTURING THE SAME

(75) Inventors: PING-SHENG SU, New Taipei (TW); JUN CHEN, Kunshan (CN); FENG-JUN QI, Kunshan (CN); QING WANG, Kunshan (CN)

(73) Assignee: HON HAI PRECISION INDUSTRY CO., LTD., New Taipei (TW)

(21) Appl. No.: 13/348,849

(22) Filed: Jan. 12, 2012

(30) Foreign Application Priority Data
Jan. 14, 2011 (CN) 201110008418.3

(51) Int. Cl. H05K 1/11; B23K 1/20; B23K 31/02

(52) U.S. Cl. 174/261; 228/180.22

(57) ABSTRACT

A flexible flat cable assembly (1), comprises: a printed circuit board (3) defining a plurality of conductive pads (31) formed thereon; and a flexible flat cable (2) electrically connected with the printed circuit board. The flexible flat cable comprises a plurality of conductors (21) arranged along a transversal direction and an insulator (22) enclosing the plurality of conductors and defining a cutout (221) to make a length of the plurality of conductors exposed out of the insulator. The plurality of the conductors are respectively contacted with the plurality of conductive pads, and each of conductor is wider than each of the conductive pad.

### FIELD OF THE INVENTION

The present invention relates to a flexible flat cable and method of assembling the same, and more particularly to a method of manufacturing a flexible flat cable assembly which has a flexible flat cable easily soldered to a printed circuit board.

### DESCRIPTION OF PRIOR ART

The flexile flat cable, FFC, is one kind of signal transmitting wire with high flexibility and high signal transmitting ability. Because of these advantages, the flexile flat cable has been applied in many electric products. When being applied, the flexile flat cable is usually coupled with an electric connector for transmitting a signal from one terminal to another terminal And, with a miniaturization of the electric connector development, a distance between two contact formed in the electric connector is small. So, a distance between two conductors of the flexible flat cable coupled to the electric connector is also need to be small. Thus, the flexible flat cable can be electrically connected to the electric connector.

In the existing technology, solder, such as tin material, is should be deposited to the conductive pads of a printed circuit board before the flexible flat cable soldered to the printed circuit board. However, when a distance between two conductors is less than 0.5 millimeter, the solder volume brushed to each conductive pad of the printed circuit board can not be controlled accurately. As a result, a short circuit phenomenon will be happened when the flexible flat cable is soldered to the printed circuit board.

As discussed above, an improved flexible flat cable assembly and method of manufacturing the same overcoming the shortages of existing technology is needed.

### SUMMARY OF THE INVENTION

Accordingly, an object of the present invention is to provide a flexible flat cable assembly which has a flexible flat cable and a printed circuit board electrically connected with each other easily and conveniently.

In order to achieve the above-mentioned objects, a flexible flat cable assembly, comprises: a printed circuit board defining a plurality of conductive pads formed thereon; and a flexible flat cable electrically connected with the printed circuit board, the flexible flat cable comprising a plurality of conductors arranged along a transversal direction, an insulator enclosing the plurality of conductors and defining a cutout to make a length of the plurality of conductors exposed out of the insulator; wherein the plurality of the conductors are respectively contacted with the plurality of conductive pads, and each of conductor is wider than each of the conductive pad.

Accordingly, an object of the present invention is to provide a method of manufacturing the flexible flat cable assembly with high efficiency and accuracy.

In order to achieve the above-mentioned objects, a method of manufacturing the flexible flat cable assembly comprising following steps: providing a steel plate having a plurality of openings; providing a printed circuit board having a plurality of conductive pads formed thereon; putting the steel plate on the printed circuit board to make the openings in alignment with the conductive pads; brushing a plurality of solder into the openings of the steel plate, thus, the plurality of solder respectively located on the plurality of conductive pads; removing the steel plate from the printed circuit board; providing a flexible flat cable having a plurality of conductors and an insulator enclosing the plurality of conductors, the insulator having a cutout to make an exposed portion of the plurality of conductors exposed out of the insulator; soldering the exposed portion of the plurality of conductors to the plurality of conductive pads through hot bar process.

Other objects, features and advantages of the invention will be apparent from the following detailed description taken in connection with the accompanying drawings.

### BRIEF DESCRIPTION OF THE DRAWINGS

FIG. 1 is a plan view of a flexible flat cable assembly in accordance with the present invention.

FIG. 2 is a plan view of a flexible flat cable of FIG. 1.

FIG. 3 is a plan view of a printed circuit board of FIG. 1.

FIG. 4 is a plan view of a steel plate which is used to brush solder to the printed circuit board of FIG. 3.

FIG. 5 is a plan view of another steel plate which is used to brush solder to the printed circuit board of FIG. 3.

FIG. 6 is a plan view of the printed circuit board brushed with solder through the steel plate shown in FIG. 4.

FIG. 7 is a plan view of the printed circuit board brushed with solder through the steel plate shown in FIG. 5.

### DETAILED DESCRIPTION OF PREFERRED EMBODIMENTS

Reference will now be made to the drawing figures to describe the present invention in detail.

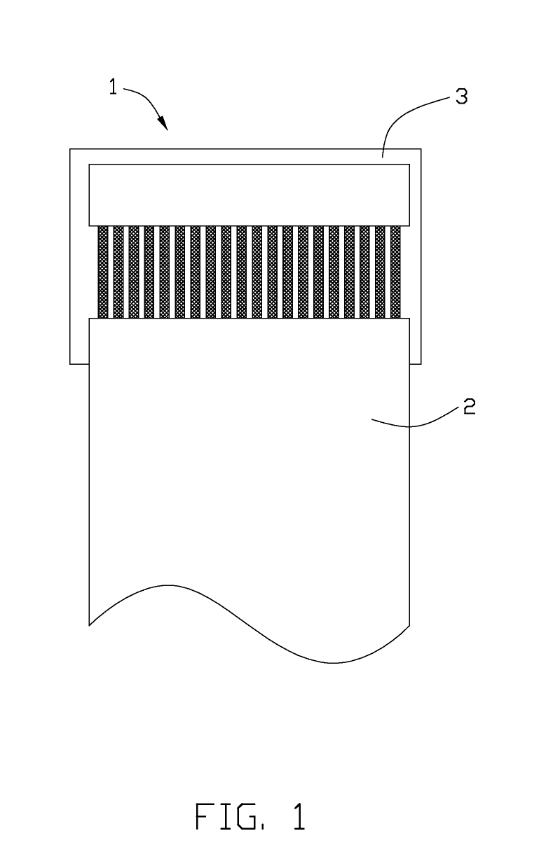

Referring to FIG. 1, a flexible flat cable assembly 1 comprises a flexible flat cable 2 and a printed circuit board 3 electrically connected with each other.

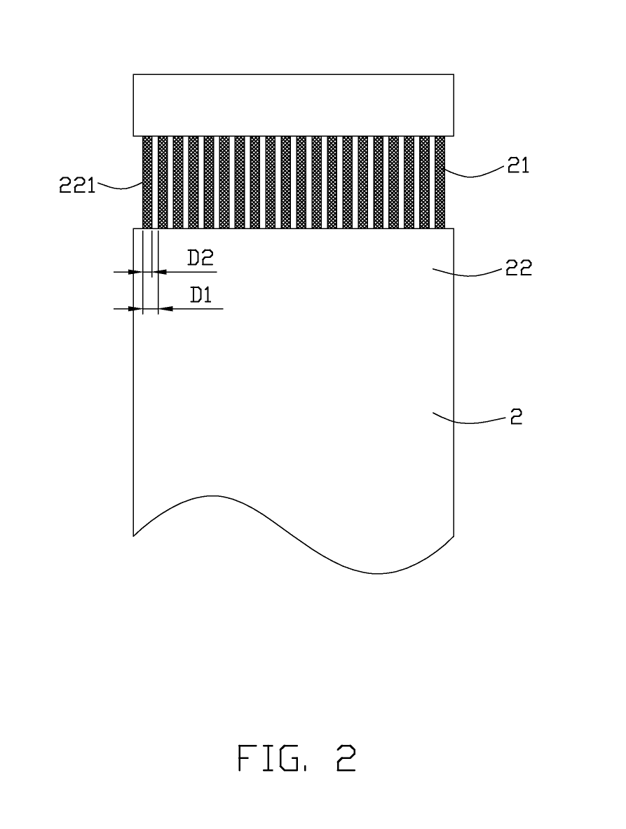

Referring to FIG. 2, the flexible flat cable 2 comprises a plurality of conductors 21 paralleled with each other and arranged along a transversal direction, and an insulator 22 enclosing the plurality of conductors 21. The insulator 22 of the flexible flat cable 2 has a cutout 221 adjacent to a free end of the flexible flat cable 2 to make a length of the plurality of conductors 21 exposed out of the insulator 22 along a vertical direction. A length of the plurality of conductors 21 exposed out of the insulator 22 can be defined as exposed sections of the conductors 21. And the free end of the plurality of conductors 21 are remain enclosed by the insulator 22. A distance (D1) between two adjacent conductors 21 of the flexible flat cable 2 is designed below 0.5 mm. So, the distance (D1) between two adjacent conductors 21 can be set to 0.5 mm, 0.4 mm, 0.3 mm, 0.2 mm etc. When the distance (D1) between two adjacent conductors 21 is set to 0.5 mm, a width of the conductor 21 is set to 0.3 mm The insulator 22 encloses the plurality of conductors 21 through laminating or extruding process. It should be noted that a distance between two adjacent conductors 21 is defined from a left side of one conductor 21 to a left side of another conductor 21.

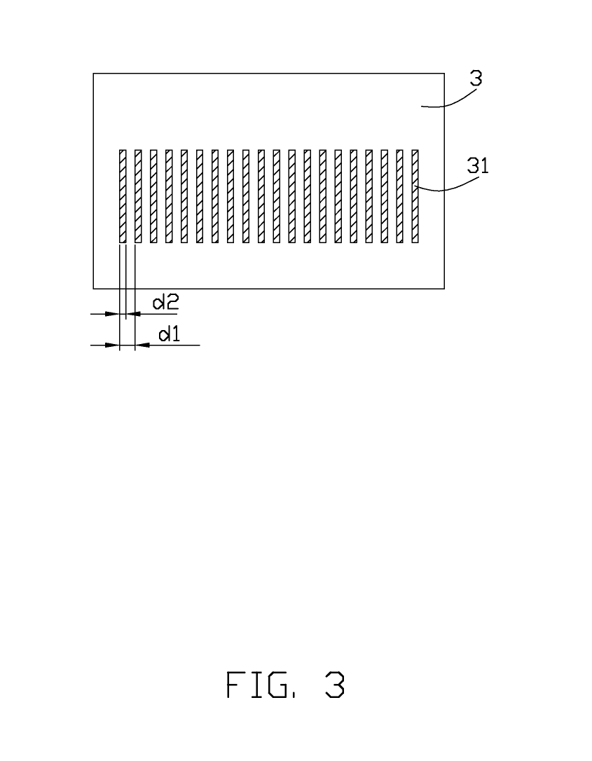

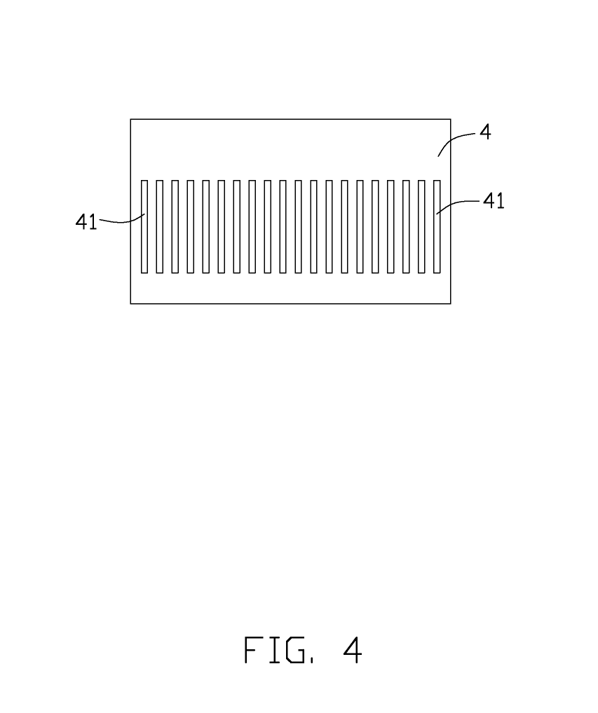

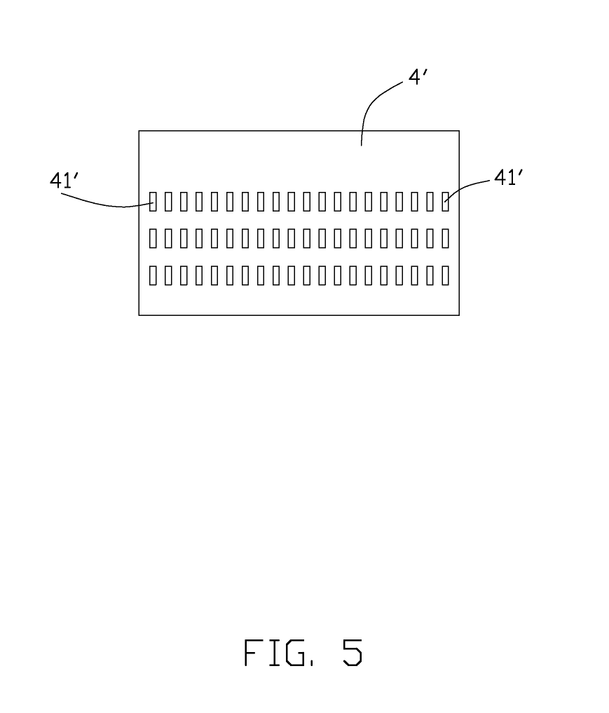

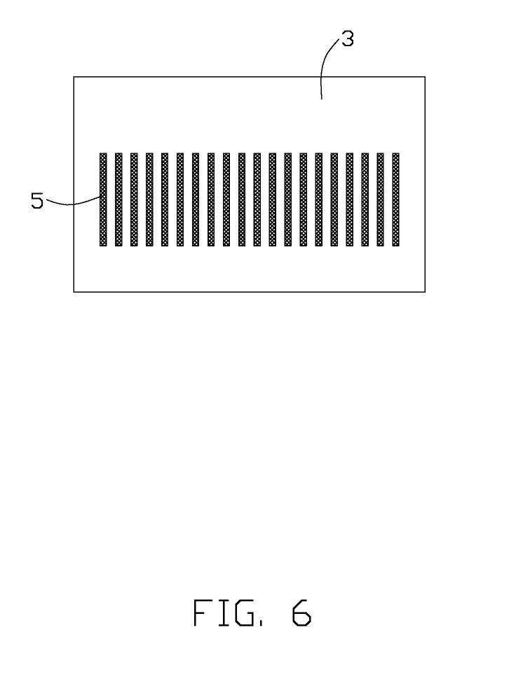

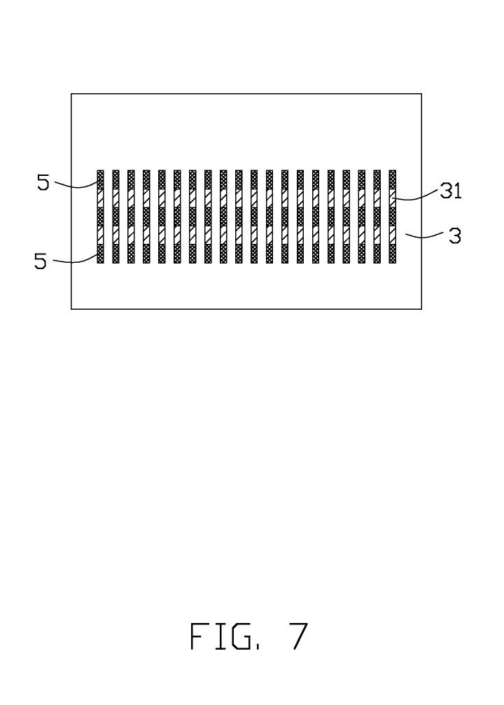

Referring to FIGS. 3 to 7, the printed circuit board 3 defines a plurality of conductive pads 31 formed on a top surface thereof A distance (d1) between two adjacent conductive pads 31 is equal to the distance between two adjacent conductors 21. And, each conductive pad 31 has a width less than that of each conductor 21. When the distance (d1) between two adjacent conductive pads 31 is set to 0.5 mm, a width of the conductive pad 31 is set to 0.2 mm. The distance (d1) between two adjacent conductive pads 31 can also be designed below 0.5 mm. And the distance (d1) between two adjacent conductive pads 31 is must equal to the distance (D1) between two adjacent conductors 21. It should be noted that a distance between two adjacent conductive pads 31 is defined from a left side of one conductive pad 31 to a left side of another conductive pad 31.

Referring to FIGS. 3 to 7, as a distance (d1) between two adjacent conductive pads 31 is below 0.5 mm and a width (d2) of the conductive pad 31 is also below 0.5 mm, the volume of solder 5 brushed to each conductive pad 31 of the printed circuit board 3 can not be controlled accurately. Thus, an additional steel plate 4 is used to cooperated with the printed circuit board 3 when the solder 5 brushed to the conductive pads 31 of the printed circuit board 3. The steel plate 4 defines a plurality of openings 41 arranged along a transversal direction and respectively in alignment with the conductive pads 31 of the printed circuit 3. The opening 41 has a size equal to that of the conductive pad 31. Thus, the volume of solder 5 can be brushed to the conductive pads 31 accurately and appropriately when the steel plate 4 attached to the printed circuit board 3. In addition, another embodiment of the steel plate 4′ of the present invention is provided. The printed circuit board 3 is need to cooperated with the steel plate 4′ when the solder 5 brushed to the conductive pads 31 of the printed circuit board 3. The steel plate 4′ defines a plurality of openings 41′ formed thereon and arranged in an arrayed manner. The opening 41′ is shorter than the opening 41. The opening 41′ has a width same to that of the conductive pad 31. Each opening 41′ is overlapped with a portion of each conductive pad 31 when the steel plate 4 attached to the printed circuit board 3. Each of the conductive pad 31 is in alignment with three openings 41′ spaced apart with each other along a longitudinal direction. Thus, the solder 5 can be brushed to three portions of the conductive pad 31 corresponding to three openings 41′ arranged along a longitudinal direction. Due to the width (d2) of the conductive pad 31 is less than the width (D2) of the conductor 21, the solder 5 will not be overflowed when the flexible flat cable 2 soldered to the printed circuit board 3.

Referring to FIGS. 1 to 7, the flexible flat cable assembly 1 in accordance with the present invention is accomplished by the following steps. Firstly, putting the steel plate 4 on the printed circuit board 3 and making the openings 41 of the steel plate 4 in alignment with the conductive pads 31 of the printed circuit board 3. Secondly, brushing the solder 5 into the openings 41 of the steel plate 4. Thus, the solder 5 is located upon the conductive pad 31 of the printed circuit board 3. The volume of the solder 5 is well controlled due to the steel plate 4. Thirdly, removing the steel plate 4 and putting the exposed sections of the conductors 21 respectively upon the conductive pads 31. At last, the conductors 21 are soldered to the conductive pads 31 through hot-bar process. In addition, the solder 5 can be brushed to the conductive pads 31 through the openings 41′ of the steel plate 4′. Three portions of each conductive pad 31 are brushed with solder 5 through steel plate 4′. Thus, each of exposed conductor 21 is electrically connected to a conductive pad 31 through three soldering section.

After the above assembling steps, the entire process of manufacturing of the flexible flat cable assembly 1 is finished. During the manufacturing of the flexible flat cable assembly 1, the solder 5 will not be overflowed when the flexible flat cable 2 soldered to the printed circuit board 3 due to the width (d2) of the conductive pad 31 is less than the width (D2) of the conductor 21. In addition, the distance between two adjacent conductors 21 of the flexible flat cable 2 will be smaller and smaller for appropriately contacting with two adjacent conductive pads 31 of the printed circuit board 3. Thus, addition steel plate 4, 4′ with openings 41, 41′ is needed to cooperate with the printed circuit board 3 for brushing the solder 5 to the conductive pads 31 accurately and conveniently. As a result, the flexible flat cable 2 is easily electrically connected to the printed circuit 3.

It will be understood that the invention may be embodied in other specific forms without departing from the spirit or central characteristics thereof The present examples and embodiments, therefore, are to be considered in all respects as illustrative and not restrictive, and the invention is not to be limited to the details given herein.

What is claimed is:

1. A flexible flat cable assembly, comprising:
a printed circuit board defining a plurality of conductive pads formed thereon; and
a flexible flat cable electrically connected with the printed circuit board, the flexible flat cable comprising a plurality of conductors arranged along a transversal direction, an insulator enclosing the plurality of conductors and defining a cutout to make a length of the plurality of conductors exposed out of the insulator; wherein the plurality of the conductors are respectively contacted with the plurality of conductive pads, and each of conductor is wider than each of the conductive pad.

2. The flexible flat cable assembly as recited in claim 1, wherein the insulator is formed by laminating or extruding process.

3. The flexible flat cable assembly as recited in claim 1, wherein the plurality of conductors are respectively soldered to the plurality of conductive pads through hot-bar process.

4. The flexible flat cable assembly as recited in claim 1, wherein a distance between two adjacent conductors is equal to a distance between two adjacent conductive pads, a width of the conductor is larger than a with of the conductive pad.

5. The flexible flat cable assembly as recited in claim 4, wherein the distance between two adjacent conductors is below 0.5 mm.

6. The flexible flat cable assembly as recited in claim 4, wherein the distance between two adjacent conductors is set to 0.5 mm, a width of the conductor is set to 0.3 mm, and a width of the conductive pad is set to 0.2 mm

7. The flexible flat cable assembly as recited in claim 3, wherein a plurality of the solder are brushed to the plurality of conductive pads for hot bar process between the conductive pads and the conductors.

8. The flexible flat cable assembly as recited in claim 1, the pair of power wires comprises a power wire and a grounding wire spaced apart with the power wire by the pair of signal wires.

9. A method of manufacturing the flexible flat cable assembly comprising following steps:
providing a steel plate having a plurality of openings;
providing a printed circuit board having a plurality of conductive pads formed thereon;
putting the steel plate on the printed circuit board to make the openings in alignment with the conductive pads;
brushing a plurality of solder into the openings of the steel plate, thus, the plurality of solder respectively located on the plurality of conductive pads;
removing the steel plate from the printed circuit board;
providing a flexible flat cable having a plurality of conductors and an insulator enclosing the plurality of conductors, the insulator having a cutout to make an exposed portion of the plurality of conductors exposed out of the insulator;
soldering the exposed portion of the plurality of conductors to the plurality of conductive pads through hot bar process.

10. The method of manufacturing the flexible flat cable assembly as recited in claim 9, wherein an opening is in alignment with a conductive pad along a vertical direction.

11. The method of manufacturing the flexible flat cable assembly as recited in claim 9, wherein three openings arranged along a longitudinal direction are in alignment with a conductive pad along a vertical direction.

12. The method of manufacturing the flexible flat cable assembly as recited in claim 9, wherein a distance between two adjacent conductive pads is equal to a distance between two adjacent conductors.

13. The method of manufacturing the flexible flat cable assembly as recited in claim 12, wherein a distance between two adjacent conductive pads is below 0.5 mm.

14. The method of manufacturing the flexible flat cable assembly as recited in claim 9, wherein the insulator is formed by laminating or extruding process.

15. The method of manufacturing the flexible flat cable assembly as recited in claim 9, wherein a width of the conductor is larger than a width of the conductive pad.

16. The flexible flat cable assembly as recited in claim 13, wherein the distance between two adjacent conductors is set to 0.5 mm, a width of the conductor is set to 0.3 mm, and a width of the conductive pad is set to 0.2 mm

17. A flexible flat cable assembly comprising:
a printed circuit board defining a plurality of conductive pads along a transverse direction; and
a flat cable defining a plurality of elongated conductors parallel to one another in said transverse direction, an insulator enclosing said conductors while exposing front portions of said conductors for soldering to the corresponding conductive pads, respectively; wherein
a pitch of the conductive pads is essentially equal to that of the conductors in said transverse direction while a width of an interface connection area between the conductive pad and the front portion of the corresponding conductor is essentially smaller than a width of each of said conductive pads in said transverse direction.

18. The flexible flat cable assembly as claimed in claim 17, wherein the front portion the conductor has the same width with other portions of the corresponding conductor while the corresponding conductive pad has a smaller width compared with the corresponding conductor.

19. The flexible flat cable assembly as claimed in claim 18, wherein said conductive pads are applied with solder via a steel plate with corresponding openings aligned with the corresponding conductive pads, respectively.

20. The flexible flat cable assembly as claimed in 19, wherein the solder is not applied to the whole conductive pad but only applied to a plurality of spaced regions of said conductive pad.
